(19) United States
(12) Patent Application Publication
(10) Pub. No.: US 2010/0229943 A1
(43) Pub. Date: Sep. 16, 2010

(54) Asymmetric Waveguide

(75) Inventor: Jin Ji, Boston, MA (US)

Correspondence Address: Milstein Zhang & Wu LLC, 49 Lexington Street, Suite 6, Newton, MA, 02465-1062, US

(73) Assignee: Lightwave Power, Inc., Cambridge, MA (US)

(21) Appl. No.: 12/725,037

(22) Filed: Mar. 16, 2010

Related U.S. Application Data
(60) Provisional application No. 61/160,451, filed on Mar. 16, 2009.
(60) Provisional application No. 61/177,449, filed on May 12, 2009.

(51) Int. Cl. H01L 31/0232

(52) U.S. Cl. 136/257; 257/E31.127

(57) ABSTRACT

An asymmetric waveguide layer which includes a metal film having an array of apertures defined in the metal film. The apertures extend from a first surface of the metal film to a second surface of the metal film. A plurality of photons have a wavelength of about X propagate through the asymmetric waveguide layer in one direction, and are substantially prevented from propagating in the other direction. An integrated solar cell is also described. First and second PV layers are disposed adjacent to and optically coupled to the asymmetric waveguide layer. A reflective layer is disposed adjacent to and optically coupled to the second PV layer second surface. Light passing through the asymmetric waveguide is substantially trapped within the second PV layer by a combination of reflection from the reflective layer and reflection by the asymmetric waveguide layer.

### CROSS-REFERENCE TO RELATED APPLICATIONS

This application claims priority to and the benefit of co-pending U.S. provisional patent application Ser. No. 61/160,451, PLANAR ONE-WAY WAVEGUIDES HAVING PERIODIC OR NON-PERIODIC SUBWAVELENGTH RESONANCE STRUCTURES, filed Mar. 16, 2009, and co-pending U.S. provisional patent application Ser. No. 61/177,449, PATTERNED PLANAR DEVICES AS INTERMEDIATE LIGHT DISTRIBUTING AND GUIDING LAYERS IN SOLAR CELLS, filed May 12, 2009, both of which applications are hereby incorporated herein by reference in their entirety.

### FIELD OF THE INVENTION

The invention relates to an asymmetric optical device in general and particularly to an asymmetric optical device that employs a surface resonance.

### BACKGROUND OF THE INVENTION

Efficient conversion of light having a wide spectrum or range of wavelengths to electricity is problematic. For example, conventional single crystal silicon solar cells absorb light having a wavelength shorter than an absorption edge wavelength, such as in the infrared range. Beyond the absorption edge of about 1100 nm, light is no longer absorbed for conversion to electricity. Because of the indirect energy band gap, prior art silicon solar cells are generally manufactured as relatively thick structures (about 200 μm) in an attempt to absorb as much as possible of the incident light having wavelengths shorter than the absorption edge. There are reports that direct bandgap behavior occurs in silicon for situations where the dimensions become small, in the micron range.

In one past attempt to improve conversion efficiency, prior art solar cells have been made using a plurality of photovoltaic (PV) layers sensitive to certain wavelength ranges. Such PV layers are wired together, typically using integrated structures, to provide the solar cell electrical output power. However, guiding light for efficient absorption and conversion by multiple PV layers remains problematic.

What is needed, therefore, is a device layer that can more efficiently guide light of particular wavelength ranges to particular PV layers of a stacked integrated solar cell structure.

### SUMMARY OF THE INVENTION

In one aspect, the invention relates to an integrated solar cell which includes a first photovoltaic (PV) layer that has a surface. An asymmetric waveguide layer includes a metal film having an array of apertures defined in the metal film. The apertures extend from a first surface of the metal film to a second surface of the metal film. The first surface of the asymmetric waveguide layer is disposed adjacent to and optically coupled to the surface of the first PV layer. A second PV layer has a second PV layer first surface that is disposed adjacent to and optically coupled to the second surface of the asymmetric waveguide layer, and which also has a second PV layer second surface. A reflective layer is disposed adjacent to and optically coupled to the second PV layer second surface. A plurality of photons which have a wavelength of about λ₁ propagate through the asymmetric waveguide layer and are substantially trapped within the second PV layer by a combination of reflection from the reflective layer and reflection by the asymmetric waveguide layer. The first PV layer and the second PV layer are electrically coupled together to provide an integrated solar cell electrical output voltage and an integrated solar cell electrical output current across an integrated solar cell positive terminal and an integrated solar cell negative terminal.

In some embodiments, the asymmetric waveguide device further comprises a first photovoltaic (PV) layer having a surface, the surface of the first PV layer disposed adjacent to and optically coupled to the first surface of the asymmetric waveguide layer; a second PV layer having a second PV layer first surface disposed adjacent to and optically coupled to the second surface of the asymmetric waveguide layer, and having a second PV layer second surface; and a reflective layer disposed adjacent to and optically coupled to the second PV layer second surface. A plurality of photons having a wavelength of about λ₁ propagate through the asymmetric waveguide layer and where the plurality of photons that propagate through the asymmetric waveguide layer are substantially trapped within the second PV layer by a combination of reflection from the reflective layer and reflection by the asymmetric waveguide layer; and the first PV layer and the second PV layer are electrically coupled together to provide an integrated solar cell electrical output voltage and an integrated solar cell electrical output current across an integrated solar cell positive terminal and an integrated solar cell negative terminal.

In some embodiments, the asymmetric waveguide layer further comprises a first dielectric medium having a first dielectric constant and a second dielectric medium having a second dielectric constant and the metal film is disposed substantially between the first dielectric medium and the second dielectric medium.

In some embodiments, a plurality of the apertures have a first surface dimension on the first surface and a second surface dimension different than the first surface dimension on the second surface.

In some embodiments, a selected one of the first PV layer and the second PV layer comprises semiconducting material selected from a group consisting of amorphous silicon, nanocrystalline silicon, microcrystalline silicon, single crystalline silicon, poly-crystalline silicon, copper indium gallium selenide, and cadmium telluride.

In some embodiments, a selected one of the first PV layer and the second PV layer comprises an organic PV material selected from a group consisting of conjugated polymers phthalocyanine, and perylene derivatives.

In some embodiments, the metal film is disposed within a dielectric medium.

In some embodiments, the asymmetric waveguide device further comprises a plurality of nanofeatures disposed on the first surface of the metal film.

In some embodiments, the metal film comprises a metal selected from the group consisting of silver, gold, copper, aluminum, nickel, silver alloy, gold alloy, copper alloy, aluminum alloy, nickel alloy, or any combination thereof.

In some embodiments, the asymmetric waveguide layer further comprises a dielectric material selected from the group consisting of a gas, a silicon dioxide, a transparent conducting oxide, a tin oxide, zinc oxide, and an indium tin oxide.

In some embodiments, the apertures are filled with a semiconducting material selected from a group consisting of amorphous silicon, nanocrystalline silicon, microcrystalline silicon, single crystalline silicon, poly-crystalline silicon, copper indium gallium selenide, and cadmium telluride.

In some embodiments, the apertures are filled with a transparent conducting oxide selected from the group consisting of tin oxide, zinc oxide, and indium tin oxide.

In some embodiments, the apertures comprise a vacuum.

In some embodiments, the apertures are filled with a gaseous medium, which can be air.

In some embodiments, the metal film is disposed substantially between a first dielectric medium having a first dielectric constant and a second dielectric medium having a second dielectric constant.

In some embodiments, the metal film comprises a first layer of a first metal film having a first dielectric constant and a second layer of a second metal film having a second dielectric constant.

In some embodiments, a plurality of the apertures is defined by the first surface to have a first dimension and is defined by the second surface to have a second dimension different from the first dimension.

In some embodiments, the asymmetric waveguide device is a layer of an integrated solar cell.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 shows one exemplary embodiment of an integrated solar cell structure having an asymmetric waveguide layer.

FIG. 2 shows an illustration of a prior art metal film optical device.

FIG. 3 shows a cross-sectional diagram illustrating one exemplary embodiment of an asymmetric waveguide layer according to the invention.

FIG. 4 shows a cross-sectional diagram illustrating another exemplary embodiment of asymmetric waveguide layer disposed within two dielectric materials.

FIG. 5 shows a cross-sectional diagram illustrating another exemplary embodiment of an asymmetric waveguide layer having two adjacent metal film layers.

FIG. 6 shows a cross-sectional diagram illustrating another exemplary embodiment of an asymmetric waveguide layer having apertures with tapered edges.

FIG. 7 shows a cross-sectional view of an exemplary asymmetric waveguide structure that was modeled.

### DETAILED DESCRIPTION

As described herein above, one problem in conventional single crystal silicon solar cells is that silicon has an indirect energy band gap, corresponding to an absorption edge of about 1100 nm. Because of this indirect energy band gap, and how silicon absorbs light energy, conventional silicon solar cells generally need to be relatively thick (˜200 μm) to efficiently absorb light having a wavelength shorter than the absorption edge.

At least in part to address this problem of efficient conversion of light over relatively wide wavelengths, the Lightwave Power Corporation has previously described, for example in co-pending PCT Application No. PCT/US09/36815, entitled INTEGRATED SOLAR CELL WITH WAVELENGTH CONVERSION LAYERS AND LIGHT GUIDING AND CONCENTRATING LAYERS, filed Mar 11, 2009, techniques of wavelength conversion layers in solar cells where the wavelength of an incident light can be converted to wavelengths more suitable for efficient absorption by particular photovoltaic (PV) layers of an integrated solar cell structure. The PCT/US09/36815 application is hereby incorporated herein by reference in its entirety for all purposes.

Definitions: The term aperture as used herein includes features such as voids, holes, and nanofeatures.

The term “substantially trapped” is defined herein to mean that of a plurality of photons that pass through an asymmetric waveguide device or layer, at least some of the plurality of photons that pass through an asymmetric waveguide device or layer are precluded, by reflection by the asymmetric waveguide device or layer, from returning through the asymmetric waveguide device or layer in the reverse direction.

In this description, the present Lightwave Power Corporation inventors describe a new type of device or integrated layer, an asymmetric waveguide. The asymmetric waveguide as described hereinbelow is believed to be useful for directing light waves through a wavelength selective layer within a stacked solar cell integrated structure and to substantially trap the photons that are transmitted through the layer. It is believed that by incorporating the inventive asymmetric waveguides described hereinbelow efficient integrated solar cells can be made with relatively thin PV layers.

The asymmetric waveguide can be thought of as roughly analogous to the apparent operation of a one-way mirror. However, since the operation of a traditional one-way mirror is actually an illusion made possible using a “trick” of the optical arts, the reference to a one-way mirror (e.g. the one-way mirror of an interrogation room) is only to give a visual impression. A conventional one-way mirror has a structure which includes a lightly reflective mirror. The conventional one-way mirror relies on gross differences of illumination on one side versus the other (e.g. the dim light on the viewing side of an interrogation room one-way mirror versus bright light in the interrogation room). Thus a conventional one-way mirror is actually a symmetric device which can pass light equally well in both directions. Thus, there is only the perception of “one-way” transmission of light by a human observer on either side of a traditional one-way mirror as a result of the illumination intensity difference.

As is described in more detail below, the structure and principles of operation of the inventive asymmetric waveguide, which is designed to transmit light of desired wavelengths in substantially one direction and not the other, are entirely different than prior art one-way mirrors as discussed above. Before describing the inventive asymmetric waveguide in detail hereinbelow, we begin with a description of exemplary embodiments of an integrated solar cell having an asymmetric waveguide layer.

Integrated Solar Cell with Asymmetric Waveguide Layer

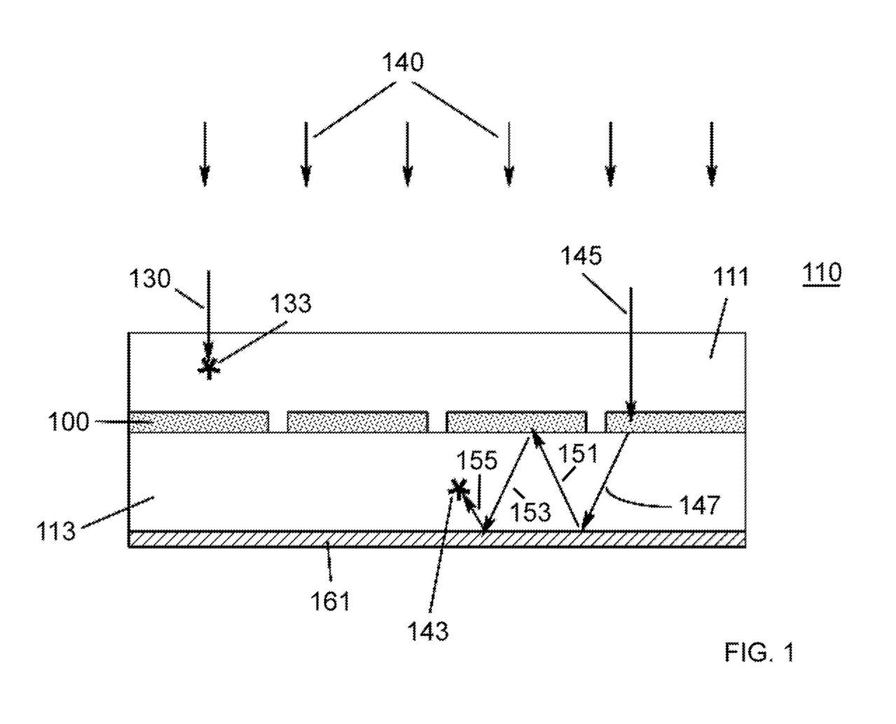

FIG. 1 shows one exemplary embodiment of an integrated solar cell 110 having an asymmetric waveguide layer 100. Light waves 140 are incident on a first surface of PV layer 111, typically referred to as a “front surface” of the solar cell. The opposite or second surface of PV layer 111 is disposed adjacent to the asymmetric waveguide layer 100. Asymmetric waveguide layer 100 is shown disposed between two PV layers, PV layer 111 and PV layer 113. PV layer 111 can be a thin layer, having a thickness of about 500 nm and an absorption range of about 300 to 500 nm. PV layer 113 can also be a relatively thin layer (compared to the 200 μm thickness of conventional solar cells) having a thickness of about 2 μm and an absorption range of light having wavelengths longer than 500 nm. A conventional mirror layer 161 is disposed adjacent to PV layer 113.

Now turning to the operation of the exemplary integrated solar cell 100, as described hereinabove, light waves 140 are incident on the front surface. Light waves having a wavelength of about 300 to 500 nm are efficiently absorbed by PV layer 111 and converted to electricity in a conventional manner. For example, a lightwave 130 having a wavelength in the range of about 300 to 500 nm can cause an absorption event 133 in PV layer 111.

Asymmetric waveguide layer 100 substantially reflects back any light outside of a desired transmission wavelength range. In the exemplary embodiment of FIG. 1, asymmetric waveguide layer 100 is configured to have a desired transmission wavelength range at or above 500 nm. Because of this wavelength selective nature of asymmetric waveguide layer 100, light waves having a wavelength of about 300 to 500 nm, and not yet absorbed by PV layer 111, are substantially reflected back into PV layer and substantially not transmitted through asymmetric waveguide layer 100 to PV layer 113. On the other hand, the light waves 145 having a wavelength greater than 500 nm and which fall within a desired transmission wavelength range are substantially transmitted through asymmetric waveguide layer 100, in a manner described in detail hereinbelow, to PV layer 113 where they can be more efficiently converted to electricity in a conventional manner. Once passed through asymmetric waveguide layer 100, also as described in more detail hereinbelow, light having a wavelength falling within the desired transmission wavelength range is substantially precluded from returning across asymmetric waveguide layer 100 due to the one-way nature of the layer. For example, a light wave represented by ray 147 that has not yet been absorbed by PV layer 113 can propagate to the mirror layer 161 where it is reflected in a conventional manner back into PV layer 113 for later absorption and conversion to electricity. As illustrated by mirror reflected light wave 151, which propagates back to asymmetric waveguide layer 100, because of the one-way propagation of light of the desired transmission wavelength range cannot pass back through asymmetric waveguide layer 100 to PV layer 111. Rather light having a wavelength falling within the desired transmission wavelength range is substantially reflected as light ray 153 shows in FIG. 1, back into PV layer 113 for absorption by PV layer 113, reflection by mirror layer 161 (e.g. light ray 153 and light ray 155) until an ultimate absorption event 143, or until it is converted to heat energy.

PV layer 111 and PV layer 113 can be manufactured using either amorphous or nanocrystalline silicon by traditional techniques. Any suitable combination of amorphous, nanocrystalline and crystalline silicon materials can be used, including, for example, a three layer device using a first layer of amorphous silicon, a second layer of nanocrystalline silicon, and a third layer of single crystal silicon. It is believed that the invention can be applied to tandem solar cells using any desired number of PV layers, such as can be made from III-V or II-VI materials using traditional methods of manufacture.

### Asymmetric Waveguides

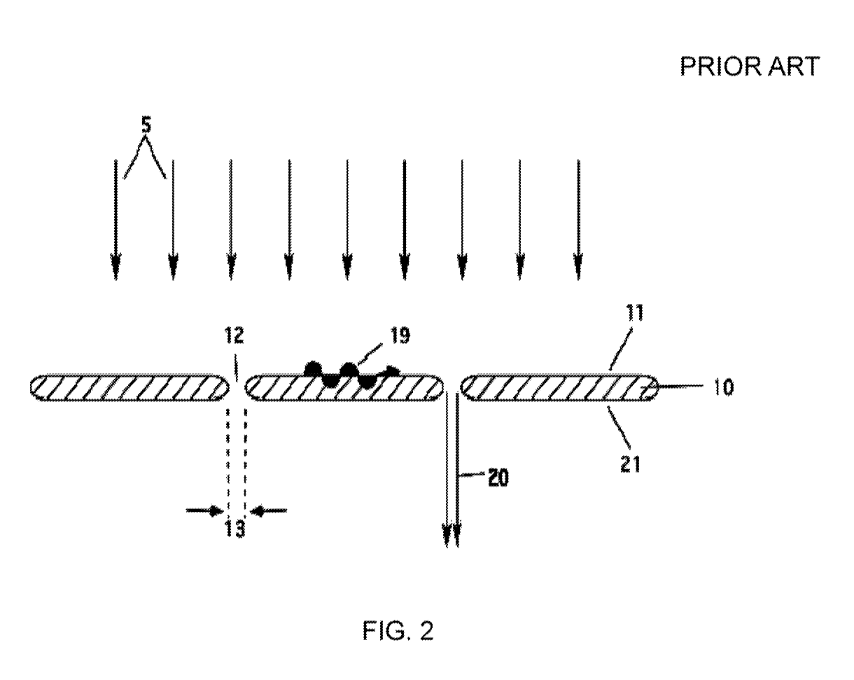

Before describing the inventive asymmetric waveguide layers in more detail, we describe the prior art device of FIG. 2. FIG. 2 shows an illustration of an optical film device of the prior art. Photons represented by light rays 5 are incident on the surface 11 of a thin metal film 10 which is surrounded by a dielectric medium (not shown). The photons of light rays 5 excite surface plasmons 19 on the surface 11. The thin metal film 10 is patterned with an array of holes 12. Holes 12 have a dimension 13 that is less than the wavelength of the photons represented by light rays 5. The dielectric constant of the metal, the dielectric constant of the surrounding medium, and the arrangement and geometry of the apertures, result in a characteristic resonant frequency ν for propagation of surface plasmons through the holes. Upon encountering these holes, surface plasmons 19 having frequency ν propagate through the holes and cause photons represented by light rays 20 to be emitted from surface 21 of thin metal film 10. Photons of light rays 5 are thus converted to photons of light rays 20, and the intensity of the photon electric field localized at the holes 12 is increased. Photons of light rays 5 having a wavelength that does not excite surface plasmons of resonant frequency ν are re-emitted from surface 11 as reflected photons (not shown). Photons that generate surface plasmons which meet the resonance condition are re-radiated as photons (e.g. photons of light rays 20) from surface 21. The structure shown in FIG. 2 is a symmetrical structure and therefore exhibits no functional difference in optical transmission or reflection for photons incident on either surface 11 or surface 21.

The inventive asymmetric waveguide is now described in detail. An asymmetric waveguide can alternatively be referred to as a planar one-way waveguide or as a planar one-way mirror (keeping in mind the distinction discussed above, where a conventional “one-way” mirror is a symmetrical device that operates by an illusion). There can also be made a loose analogy to an electronic diode device which conducts an electrical current in only one direction. However, when considering the one-way propagation of light of about a desired wavelength of light across an asymmetric waveguide layer in only one direction, the diode analogy is somewhat limited, since for example, a diode device need not be used as a wavelength selective element, and generally is used independent of wavelength or frequency.

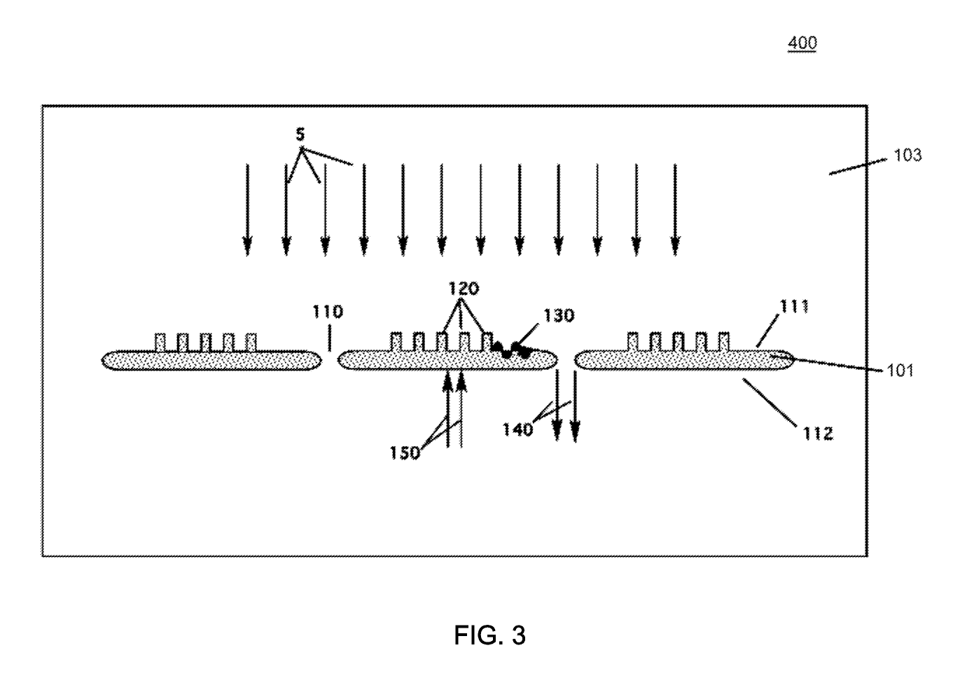

FIG. 3 shows a cross-sectional diagram illustrating one exemplary embodiment of an asymmetric waveguide fabricated as an asymmetric waveguide layer 400. A metal film 101 is surrounded by a dielectric medium 103. An array of features or apertures (e.g., voids, holes, or nanofeatures) is disposed within metal film 101. For example, apertures 110 extend in film 101 from a first surface 111 of metal film 101 to a second surface 112. Resonant features 120 are shown as ridges provided on the first surface 111. The scale and spacing of these resonant features 120 are configured to select a first resonant frequency ν₁ for surface 111, as well as a resonance width ν_{σ}.

Turning now to the operation of the structure of FIG. 3, photons represented by light rays 5 are incident on the first surface 111. Surface plasmons 130 of frequency ν₁ are excited when photons of light rays 5, incident on surface III, have a corresponding resonance wavelength λ₁. Surface 112 is not provided with the same resonant features 120, and therefore has a different resonance frequency ν₂. When light having a wavelength of about λ₁ is incident on the surface 111, the light excites surface plasmons 130 that propagate through an aperture 110 to surface 112 and then re-radiates photons such as are illustrated by light rays 140. However, if photons represented by light rays 150 having the same wavelength λ₁ are incident on surface 112 (typically having no resonant features 120), the light does not meet the resonance conditions of surface 112, and therefore the light does not excite surface plasmons on surface 112. Photons of light rays 150 having a wavelength λ₁ are reflected by surface 112. Thus, the transmission from surface 112 to surface 111 through apertures 110 in the metal film 100 for photons having a wavelength λ₁ is substantially precluded (true one-way operation) because of the absence of the surface plasmons that have frequency equal to the resonance frequency of surface 112.

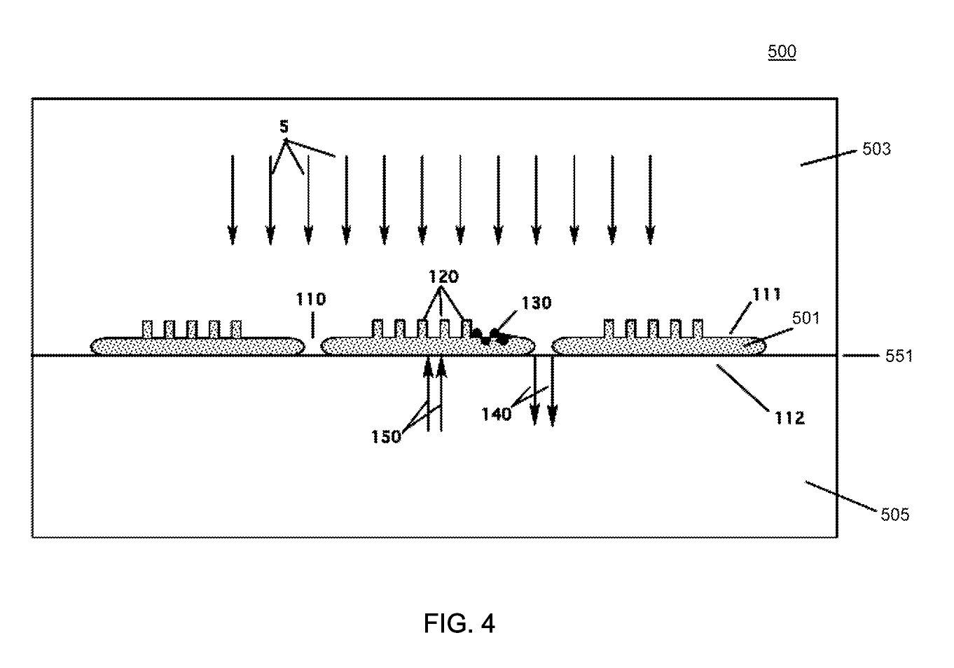

FIG. 4 shows a cross-sectional diagram which illustrates another exemplary embodiment of an asymmetric waveguide layer 500. A metal film has plurality of apertures 110 throughout the film, extending from a surface 111 to a surface 112. In the embodiment of FIG. 4, metal film 501 optionally includes nanofeatures 120 as described hereinabove. Metal film 501 is disposed between a first medium 503 and a second medium 505. First medium 503 is typically made of a different material than second medium 505. There is an interface 551 between first medium 503 and second medium 505. Medium 505 has a different dielectric constant than the dielectric constant of medium 503. Either surface 111 or surface 112 can be disposed at the interface of first medium 503 and second medium 505. In the embodiment of FIG. 4, interface 551 is shown as co-located with surface 112. Typically, but not necessarily, apertures 110 can be filled with the material of either medium 503 or medium 505 (depending on which surface is closer to or at the interface of the two media, or apertures 110 can be empty (e.g., containing vacuum) or filled with another third type of dielectric medium (e.g., a gas or a solid). Medium 503 and the arrangement of apertures 110 (and optional features 120) are configured to provide a surface 111 resonant wavelength of λ₁. The combination of medium 505 and apertures 110 is configured to cause surface 112 to have a different resonance wavelength λ₂. The dielectric constant of the material of medium 505 causes surface 112 to exhibit a different resonant frequency ν₂ from the resonant frequency ν₁ of surface 111.

Now turning to the operation of the of asymmetric waveguide layer 500 of FIG. 4, the photons of an incident light (as illustrated by light rays 5) to surface 111 having a wavelength of about λ₁, excite surface plasmons 130 that, because the resonance condition ν₁ is met, propagate through apertures 110 to surface 112 where light of wavelength of about λ₁ is emitted (as illustrated by light rays 140). In the embodiment of FIG. 4, the resonance condition ν₁ is a function of the aperture array geometry, any nanofeature geometry that is present (e.g., optional features 120), the dielectric constant of medium 503, and the dielectric constant of metal film 501. When the resonance condition is met, then surface plasmons 130 propagate through apertures 110, and are re-radiated as photons 140 into dielectric medium 505. On the other hand, when light rays 150 having a wavelength of about λ₁ are incident on the second surface 112, the photons of light rays 150 do not meet the resonance condition λ₂ for second surface 112. Therefore, a light ray 150 having a wavelength λ₁ incident at the surface 112 does not pass through the metal film 501 back to surface 111. Reflected photons of light ray 151 are converted to electricity by an underlying PV layer, or if not converted to electricity, photons 151 are eventually converted to heat in medium 505 or in an adjacent layer.

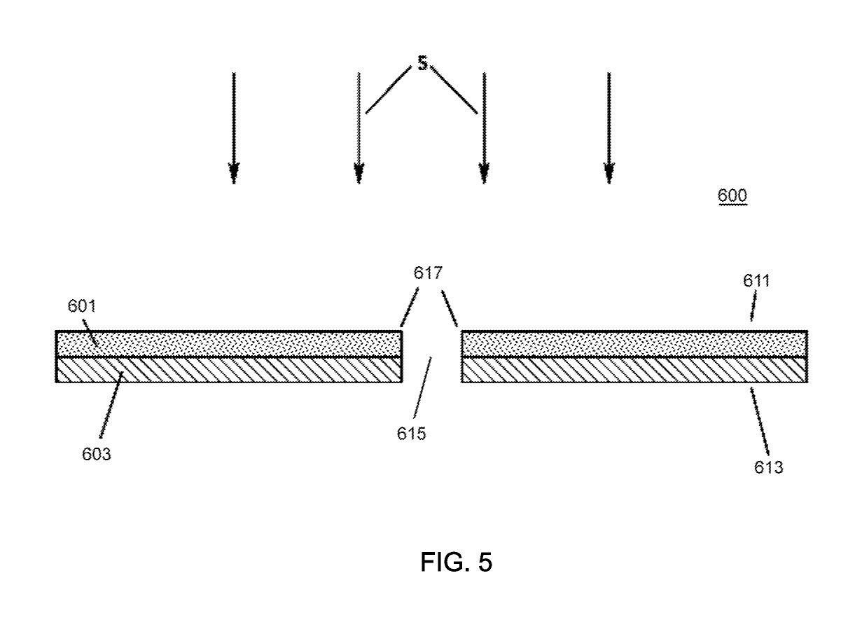

FIG. 5 shows a cross-sectional diagram illustrating another exemplary embodiment of asymmetric waveguide layer 600. Asymmetric waveguide layer 600 is manufactured with two adjacent metal film layers, metal film layer 601 and metal film layer 603. Light rays 5 are shown incident on the surface 611 of metal layer film 601 in FIG. 5. Surface plasmons (not shown) that satisfy the resonant conditions of surface 611 propagate through asymmetric waveguide layer 600 to the surface 613 of metal film layer 603. In this embodiment of FIG. 5, the resonance wavelength depends on the dielectric constants of both metal films. Light incident on surface 611 is subject to resonance conditions related to metal film layer 601, and light incident on surface 613 is subject to resonance conditions related to metal film layer 603. Any of the other techniques described herein for modifying the resonance frequency can also be applied to the structure illustrated in FIG. 5, including, for example, the addition of nanoscale features on either or both surfaces.

In some embodiments, such as the embodiment of FIG. 5, the edges 617 of the apertures can be of sharp relief. Such sharp edges can be created, for example, by an image reversal photolithography and lift-off processes. Rounded edges as shown in FIG. 3 and FIG. 4 can be provided in manufacture, for example, by use of wet or dry etching processes.

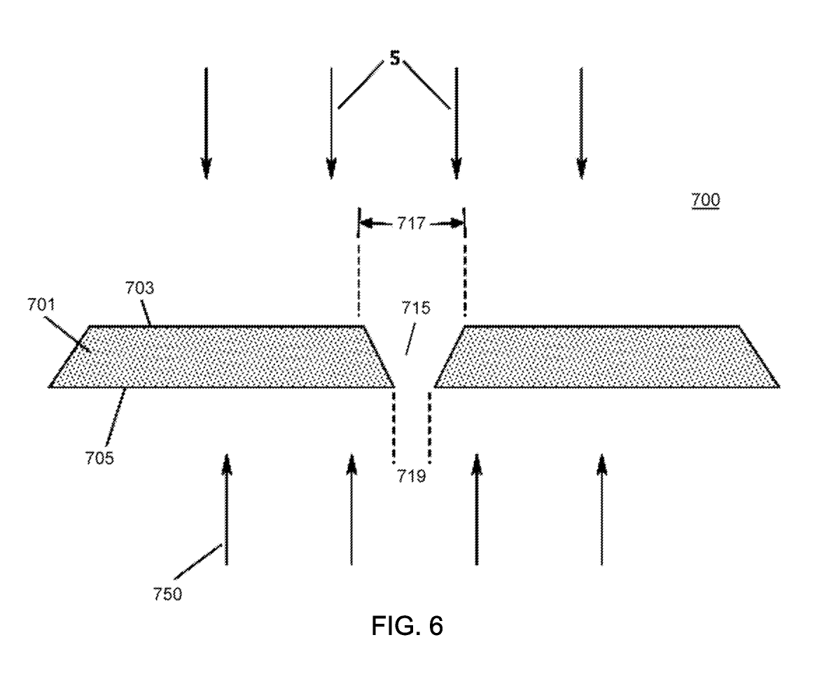

FIG. 6 shows a cross-sectional diagram illustrating another exemplary embodiment of asymmetric waveguide layer 700 having apertures with tapered edges. Metal film layer 701 includes apertures 715 having a dimension 717 on surface 703 and a dimension 719 on surface 705. Such metal relief profiles can be formed, for example, by a combination of lift-off and etching or by other means. Tapered edge structures can provide a broadened width of the resonance wavelengths and/or cause the resonance frequencies to depend on the surface of incidence. In operation, still referring to FIG. 6, photons represented by light rays 5 incident on surface 703 generate surface plasmons subject to a resonance condition that depends on the dimension 717 of the tapered aperture 715. Photons represented by light rays 750 incident on surface 705 are subject to a resonance condition of surface 705 which depends in part on dimension 719 of aperture 715. Thus, the tapering of the aperture provides a further asymmetry between the resonant surface plasmon frequency of surface 703 and the resonant surface plasmon frequency of surface 705.

Dennis Slafer of the MicroContinuum Corporation of Cambridge, Mass., has described several manufacturing techniques and methods that are believed to be suitable for the manufacture of asymmetric waveguides as described herein. For example, U.S. patent application Ser. No. 12/358,964, ROLL-TO-ROLL PATTERNING OF TRANSPARENT AND METALLIC LAYERS, filed Jan. 23, 2009, describes and teaches one exemplary manufacturing process to create metallic films having a plurality of nanofeatures suitable for use in surface plasmon wavelength converter devices as described herein. Also, U.S. patent application Ser. No. 12/270,650, METHODS AND SYSTEMS FOR FORMING FLEXIBLE MULTILAYER STRUCTURES, filed Nov. 13, 2008, U.S. patent application Ser. No. 11/814,175, REPLICATION TOOLS AND RELATED FABRICATION METHOD AND APPARATUS, filed Aug. 4, 2008, U.S. patent application Ser. No. 12/359,559, VACUUM COATING TECHNIQUES, filed Jan. 26, 2009, and PCT Application No. PCT/US2006/023804, SYSTEMS AND METHODS FOR ROLL-TO-ROLL PATTERNING, filed Jun. 20, 2006 describe and teach related manufacturing methods which are also believed to be useful for manufacturing asymmetric waveguides as described herein. Each of the above identified United States and PCT applications is hereby incorporated herein by reference in its entirety for all purposes.

Laser interferometry is another manufacturing process that is believed to be suitable for the manufacture of asymmetric waveguides as described herein. For example, in U.S. Pat. No. 7,304,775B2, Actively stabilized, single input beam, interference lithography system and method, D. Hobbs and J. Cowan described an interference lithography system that is capable of exposing high resolution patterns in photosensitive media and employing yield increasing active stabilization techniques. U.S. Pat. No. 7,304,775 is hereby incorporated herein by reference in its entirety for all purposes.

In one exemplary process, a substrate is coated with photoresist, exposed to a laser source at defined regions that represent a complementary pattern of the desired nanopattern. Then the photoresist material is developed and the complementary nanopattern is formed in the photoresist material. This complementary nanopattern is then used as a template for the next stage in the process, which consists of deposition of the nanopatterned material (gold, silver, etc.) through a number of deposition techniques such as electron-beam evaporation and sputtering deposition. The remaining photoresist is then lifted off by chemical reagents, leaving behind the desired asymmetric waveguide.

Turning now to materials useful for the manufacture of asymmetric waveguides, asymmetric waveguides can be made of any suitable conductor, such as for example, silver, gold, copper, aluminum, nickel, silver alloy, gold alloy, copper alloy, aluminum alloy, nickel alloy, or any combination thereof. Apertures (e. g., voids, holes, or nanofeatures) and/or media (e.g., dielectric media) can be present as a dielectric material, such as for example, a gas, air or silicon dioxide or a transparent conducting oxide such as tin oxide, zinc oxide, or indium tin oxide, or a semiconducting material such as silicon in any suitable form, such as for example, amorphous, crystalline, microcrystalline, nanocrystalline, or polycrystalline silicon. Copper indium gallium selenide (CIGS), and cadmium telluride (CdTe) are believed to be other suitable semiconducting materials. The apertures and/or media can be of different materials.

Other exemplary embodiments asymmetric waveguides (not shown in the drawings) can include combinations of any of the above structures to configure resonant conditions on the first surface when light is incident on the first surface, while ensuring non-resonant conditions on the second surface when light is incident on the second surface. Suitable apertures can take any form, including but not limited to, round or elliptical holes, slits, polygons, or irregular shapes. Resonant features can be of any suitable shape or morphology such as, but not limited to, ridges, bumps, depressions, and can be formed in any pattern including rings or gratings surrounding the aperture. The plurality of apertures as described in various embodiments can be periodic, non-periodic, or any combination thereof.

### Example

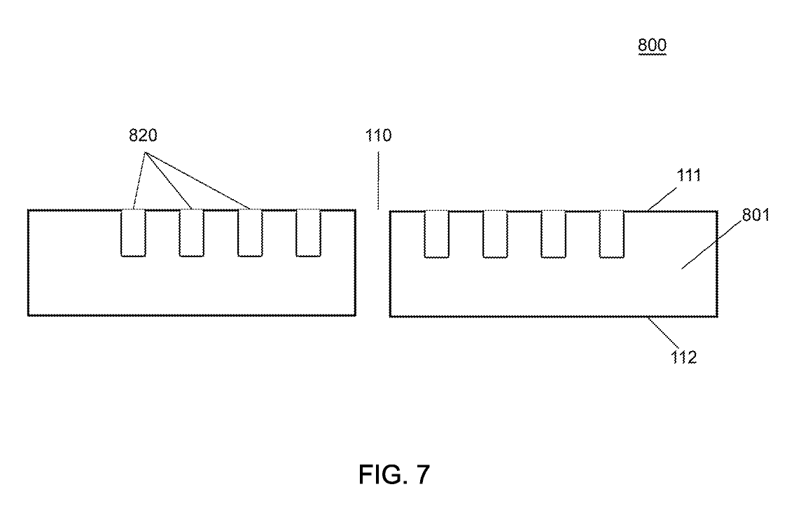

FIG. 7 shows a cross-sectional view of an exemplary structure believed suitable for use as an asymmetric waveguide 800. Asymmetric waveguide 800 was modeled using a Finite-Difference Time-Domain (FDTD) method.

Beginning with the structure of FIG. 7, exemplary asymmetric waveguide 800 included a single sub-wavelength aperture 110 in an optically thick silver film 801. Surface 111 of film 801 had four concentric grooves 820 which surrounded aperture 110. The diameter of aperture 110 was 250 nm. Groves 820 had a periodicity of 500 nm, a groove depth of 60 nm, and a width of 300 nm. The film 801 thickness was 115 nm. The design of the nanopattern and the choice parameters of its nanofeatures of asymmetric waveguide 800 were made to create a resonant condition on surface 111 at about a wavelength of 650 nm. The concentric groves 820 on surface 111 were resonant features which allowed coupling of incident light having a wavelength of about 650 nm into surface plasmons on surface 111.

The modeling results described hereinbelow give evidence that a structure such as asymmetric waveguide 800 can enable strong light transmission for light of a given wavelength range from surface 111 to 112, while limiting transmission of light of about the same wavelength range from surface 112 to 111 to a relatively small value. Theoretical calculation using the FDTD method was used to test whether light transmission from surface 111 to 112 has significantly higher intensity than transmission in the reverse direction for the exemplary structure of FIG. 7 with concentric grooves (e.g., resonant structures 820) on surface 111 and no such features present on surface 112. The method used Maxwell's equations to treat interactions between electromagnetic waves and nanofeatures and predict intensity and spectra of light transmission. The calculation indicated that transmission intensity in the forward direction (surface 111 to surface 112) was about 5 times as much as the reverse transmission intensity through the aperture (surface 112 to surface 111). This calculation gives an indication of the functionality of an asymmetric waveguide.

It is believed that any of the asymmetric waveguide structures described herein are capable of blocking at least 50% of the photons that pass across the asymmetric waveguide from returning in a reversed direction (one-way operation). The modeled example (FIG. 7) achieved a forward transmission to reverse transmission ratio of about 5:1. It is believed that far higher ratios can be realized and that more efficient asymmetric waveguides (e.g., one-way nanopatterned devices) can be made using the principles, techniques, and materials, described hereinabove and that reverse transmission in certain wavelength ranges can be substantially precluded.

### CONCLUSION

An asymmetric waveguide (one-way light waveguide) that allows electromagnetic waves to travel in only one direction is desirable in many fields such as solar and integrated optics. In solar cell optics for instance, asymmetric waveguides can be implemented as integrated layers adjacent to photovoltaic materials to ensure the guiding of sunlight into photovoltaic materials and to trap selected wavelengths of the light within the photovoltaic materials by restricting light of about certain wavelengths from traveling in the reverse direction. In this application, asymmetric waveguides can receive and direct incident light through a large planar area. Other applications for the new optical structures described herein beyond solar cell applications, are believed to include generalized wavelength selective propagation and trapping and wavelength selective light concentration.

The inventive asymmetric waveguide (planar one-way waveguide) device is based in part on transmission by use of plasmonic resonance. The device includes two surfaces where the first surface includes resonant features or resonant conditions to enable transmission of light incident on that surface to the second surface, whereas the second surface lacks resonant features or conditions so as to substantially forbid transmission of light incident on that surface to the first surface. Light outside of the resonant wavelength range of the second surface is therefore reflected off the second surface. As a result, the light falling with the wavelength resonance range of the first surface is substantially allowed to travel through the asymmetric waveguide device or layer from a first surface to a second surface and substantially blocked from returning from the second surface to the first surface. As described hereinabove, examples of such resonant features include: grooves, ridges, ripples, holes, etc. Examples of resonant conditions, also as described hereinabove, include: an interfacing medium or an interfacing metallic surface. Such resonant conditions are believed to be explained by the equations of the theoretical description which follows.

### Theoretical Description

Periodic or non-periodic nanostructures having sub-wavelength apertures and resonant features (e.g., as fabricated in a thin metallic planar substrate) have been shown to transmit extraordinary amount of incident electromagnetic radiation of selected frequencies even though the apertures are of sub-wavelength size. Such structures have also been shown to have the capability to generate enhanced electric fields and to perform nonlinear optical conversion. These phenomena can be explained at least in part as resulting from the excitation of surface plasmons (a collective oscillation of free electrons existing in metals) when a resonant condition between the electromagnetic waves and surface plasmons is satisfied. For a periodic structure such as periodic array of apertures, this resonant condition can be described as:

$$λ = {a}_{0} \sqrt{\frac{{ɛ}_{1} {ɛ}_{2}}{{ɛ}_{1} + {ɛ}_{2}}} \qquad ( 1 )$$

where λ is the wavelength of the incident electromagnetic radiation; a₀ is the lattice constant; ε₁ and ε₂ are real portions of the respective dielectric constants for the metallic substrate and the surrounding medium in which the incident radiation passes prior to irradiating the metal film. For a non-periodic structure, the above equation may be modified to describe the resonant condition for a non-periodic structure. For example, where configuration includes a single aperture at the center of a single annular groove, the resonant condition may be described as:

$$λ = ρ \sqrt{\frac{{ɛ}_{1} {ɛ}_{2}}{{ɛ}_{1} + {ɛ}_{2}}} \qquad ( 2 )$$

where ρ denotes the radius of the annular groove from the centrally positioned aperture within the annular groove.

Present one-way waveguides use magneto-optical materials with magnetic domain walls. These present one-way waveguide devices realize one-way wave-guiding by absorbing or canceling out light waves traveling in the directions other than the intended directions. Such magneto-optic devices are complex, and have limited effective path lengths and areas in the micrometer range. As such, the effective area to receive and direct light is often at micrometer range as well.

By contrast, in the inventive asymmetric waveguide, efficient light transmission through sub-wavelength structures can be achieved by satisfying resonant conditions described by equations (1) and (2). At the same time, efficient light transmission through sub-wavelength structures can be substantially forbidden by not satisfying resonant conditions described by equations (1) and (2).

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. An asymmetric waveguide device comprising:
a metal film having an array of apertures defined in said metal film, said apertures extending from a first surface of said metal film to a second surface of said metal film, said first surface configured to have a first resonant frequency ν₁ and said second surface configured to have a second resonant frequency ν₂;
said metal film configured to permit a plurality of photons having a wavelength of about λ₁ incident on said first surface to pass through said apertures to said second surface and at least one photon incident on said first surface having a wavelength different from said first wavelength λ₁ is precluded from passing through any of said apertures to said second surface; and
wherein at least some of said plurality of photons having a wavelength of about λ₁ that pass through said apertures to said second surface are precluded from returning through the second surface in the reverse direction.

2. The asymmetric waveguide device of claim 1, further comprising:
a first photovoltaic (PV) layer having a surface, said surface of said first PV layer disposed adjacent to and optically coupled to said first surface of said asymmetric waveguide layer;
a second PV layer having a second PV layer first surface disposed adjacent to and optically coupled to said second surface of said asymmetric waveguide layer, and having a second PV layer second surface; and
a reflective layer disposed adjacent to and optically coupled to said second PV layer second surface;
wherein a plurality of photons having a wavelength of about λ₁ propagate through said asymmetric waveguide layer and where said plurality of photons that propagate through said asymmetric waveguide layer are substantially trapped within said second PV layer by a combination of reflection from said reflective layer and reflection by said asymmetric waveguide layer; and
wherein said first PV layer and said second PV layer are electrically coupled together to provide an integrated solar cell electrical output voltage and an integrated solar cell electrical output current across an integrated solar cell positive terminal and an integrated solar cell negative terminal.

3. The asymmetric waveguide device of claim 2, wherein said asymmetric waveguide layer further comprises a first dielectric medium having a first dielectric constant and a second dielectric medium having a second dielectric constant and said metal film is disposed substantially between said first dielectric medium and said second dielectric medium.

4. The asymmetric waveguide device of claim 2, wherein a plurality of said apertures have a first surface dimension on said first surface and a second surface dimension different than said first surface dimension on said second surface.

5. The asymmetric waveguide device of claim 2, wherein a selected one of said first PV layer and said second PV layer comprises semiconducting material selected from a group consisting of amorphous silicon, nanocrystalline silicon, microcrystalline silicon, single crystalline silicon, poly-crystalline silicon, copper indium gallium selenide, and cadmium telluride.

6. The asymmetric waveguide device of claim 2, wherein a selected one of said first PV layer and said second PV layer comprises an organic PV material selected from a group consisting of conjugated polymers phthalocyanine, and perylene derivatives.

7. The asymmetric waveguide device of claim 1, wherein said metal film is disposed within a dielectric medium.

8. The asymmetric waveguide device of claim 1, further comprising a plurality of nanofeatures disposed on said first surface of said metal film.

9. The asymmetric waveguide device of claim 1, wherein said metal film comprises a metal selected from the group consisting of silver, gold, copper, aluminum, nickel, silver alloy, gold alloy, copper alloy, aluminum alloy, nickel alloy, or any combination thereof.

10. The asymmetric waveguide device of claim 1, wherein said asymmetric waveguide layer further comprises a dielectric material selected from the group consisting of a gas, a silicon dioxide, a transparent conducting oxide, a tin oxide, zinc oxide, and an indium tin oxide.

11. The asymmetric waveguide device of claim 1, wherein said apertures are filled with a semiconducting material selected from a group consisting of amorphous silicon, nanocrystalline silicon, microcrystalline silicon, single crystalline silicon, poly-crystalline silicon, copper indium gallium selenide, and cadmium telluride.

12. The asymmetric waveguide device of claim 1, wherein said apertures are filled with a transparent conducting oxide selected from the group consisting of tin oxide, zinc oxide, and indium tin oxide.

13. The asymmetric waveguide device of claim 1, wherein said apertures comprise a vacuum.

14. The asymmetric waveguide device of claim 1, wherein said apertures are filled with a gaseous medium.

15. The asymmetric waveguide device of claim 1, wherein said metal film is disposed substantially between a first dielectric medium having a first dielectric constant and a second dielectric medium having a second dielectric constant.

16. The asymmetric waveguide device of claim 1, wherein said metal film comprises a first layer of a first metal film having a first dielectric constant and a second layer of a second metal film having a second dielectric constant.

17. The asymmetric waveguide device of claim 1, wherein a plurality of said apertures is defined by said first surface to have a first dimension and is defined by said second surface to have a second dimension different from said first dimension.

18. The asymmetric waveguide device of claim 1, wherein said asymmetric waveguide device is a layer of an integrated solar cell.
